(19) United States
(12) Patent Application Publication
(10) Pub. No.: US 2013/0277100 A1
(43) Pub. Date: Oct. 24, 2013

(54) TOUCH PANEL AND METHOD OF MANUFACTURING THE SAME

(71) Applicants: Seung Hyun Ra, Gyunggi-do (KR); Jin Uk Lee, Gyunggi-do (KR)

(72) Inventors: Seung Hyun Ra, Gyunggi-do (KR); Jin Uk Lee, Gyunggi-do (KR)

(73) Assignee: SAMSUNG ELECTRO-MECHANICS CO., LTD., Gyunggi-do (KR)

(21) Appl. No.: 13/532,454

(22) Filed: Jun. 25, 2012

(30) Foreign Application Priority Data
Apr. 19, 2012 (KR) 1020120040986

(51) Int. Cl. H05K 1/00; H05K 3/06; H05K 3/10

(52) U.S. Cl. 174/268; 427/97.3; 427/97.4; 216/13

(57) ABSTRACT

Disclosed herein are a touch panel and a method of manufacturing the same. The touch panel includes a transparent substrate, an insulating layer that is formed on the transparent substrate and has an intaglio portion formed thereon, an electrode layer that is embedded in the intaglio portion, and a light absorbing layer that is formed in an inner wall of the intaglio portion to be interposed between the inner wall of the intaglio portion and the electrode layer. In the touch panel, the electrode layer is formed to be embedded, and the light absorbing layer is further included, thereby durability and visibility of the touch panel.

### CROSS REFERENCE TO RELATED APPLICATION

This application claims the benefit of Korean Patent Application No. 10-2012-0040986, filed on Apr. 19, 2012, entitled “Touch Panel and Method of Manufacturing The same”, which is hereby incorporated by reference in its entirety into this application.

### BACKGROUND OF THE INVENTION

1. Technical Field

The present invention relates to a touch panel and a method of manufacturing the same.

2. Description of the Related Art

With the development of computers using digital technology, computer assisted devices have been developed, and personal computers, portable transmission devices, information processing devices exclusive for individual, and the like perform a text and graphic process using a variety of input devices such as a keyboard, a mouse, and the like.

However, since the use of the computer has been gradually widened with rapid progress of the information society, there are difficulties in effectively driving products only using the keyboard and the mouse currently acting as an input device. Accordingly, there is a demand for an input device which has simple operation and less erroneous operation and allows information input to be easily performed by anyone.

In addition, in input device-related technologies, concerns have been changed toward high reliability, durability, innovativeness, design and processing-related technology, and the like in addition to satisfying general functions. Here, to achieve these purposes, as an input device in which information such as text, graphics, and the like can be input, a touch screen has been developed.

The touch panel is mounted on a display surface of an image display apparatus including a flat panel display device such as an LCD (liquid crystal display) a PDP (plasma display panel), an EL (electroluminescence), or the like, and a CRT (cathode ray tube), and is used to allow a user to select his desired information while viewing the image display apparatus.

Types of touch panels are classified into a resistive type, a capacitive type, an electro-magnetic type, a SAW (surface acoustic wave) type, and an infrared type. The touch panels having these various types are applied to electronic products based on problems of signal amplification, resolution difference, the difficulty of design and processing technology, optical characteristics, electrical characteristics, mechanical characteristics, environment resistance characteristics, durability, input characteristics, and affordability, and a resistive touch panel and a capacitive touch panel are currently and widely used.

These touch panels typically form an electrode layer using ITO (indium tin oxide). However, ITO has excellent electrical conductivity, but indium that is a raw material is very expensive as a rare-earth metal. In addition, since indium is expected to be depleted within the next 10 years, supply/demand thereof will not be smoothly achieved.

For these reasons, as disclosed in Korean Patent Laid-Open Publication No. 10-2010-0091497, research for forming an electrode layer using metals have been actively conducted. The electrode layer made of metal has excellent electrical conductivity compared to ITO, and has advantages that supply/demand of metals is smoothly achieved. However, the above-described conventional touch panel has a problem such that visibility of the touch panel is deteriorated due to glare occurring on the electrode layer when light is irradiated from the outside. In addition, the conventional touch panel is structurally weak because an electrode pattern is formed to be protrusively formed on a transparent substrate.

### SUMMARY OF THE INVENTION

The present invention has been made in an effort to provide a touch panel and a method of manufacturing the same which may improve visibility of the touch panel by preventing glare from occurring on an electrode layer made of metals when light is irradiated from the outside.

In addition, the present invention has been made in an effort to provide a touch panel and a method of manufacturing the same which may improve durability by preventing an electrode pattern from being protrusively formed due to a structure of the touch panel.

According to a preferred embodiment of the present invention, there is provided a touch panel, including: a transparent substrate; an insulating layer that is formed on the transparent substrate and has an intaglio portion formed thereon; an electrode layer that is embedded in the intaglio portion; and a light absorbing layer that is formed in an inner wall of the intaglio portion to be interposed between the inner wall of the intaglio portion and the electrode layer.

Here, the touch panel may further include a seed layer that is formed between the light absorbing layer and the electrode layer.

In addition, the touch panel may further include a protective layer that is formed on the insulating layer.

In this instance, the protective layer may be made of transparent resin.

In addition, the insulating layer may be made of thermosetting resin or photocurable resin.

In addition, the electrode layer may be made of a metal consisting of one of copper (Cu), aluminum (Al), gold (Au), silver (Ag), titanium (Ti), palladium (Pd), and chromium (Cr), or a combination thereof.

In addition, the light absorbing layer may include an ink layer, and more particularly, may be made of black ink.

In addition, the light absorbing layer may be formed of a metal oxide layer, and more particularly, the metal oxide layer may be made of one of copper oxide (CuO or Cu₂O), aluminum oxide (Al₂O₃), silver oxide (AgO or Ag₂O), titanium oxide (TiO₂), palladium oxide (PdO), and chromium oxide (CrO, CrO₃, or Cr₂O₃), or a combination thereof.

According to another preferred embodiment of the present invention, there is provided a method of manufacturing a touch panel, including: forming an insulating layer on a transparent substrate; forming an intaglio portion on the insulating layer; forming a light absorbing layer in an inner wall of the intaglio portion; and forming an electrode layer in the intaglio portion.

Here, the forming of the intaglio portion may pattern the insulating layer using a stamp to form the intaglio portion.

In addition, the forming of the light absorbing layer may immerse, in ink, the transparent substrate on which the insulating layer is formed, dry the immersed transparent substrate, and remove the ink formed on the insulating layer excluding the intaglio portion to thereby form the light absorbing layer.

In this instance, the ink may be black ink.

In addition, the forming of the light absorbing layer may form a metal oxide layer on the insulating layer, and remove the metal oxide layer formed on the insulating layer excluding the intaglio portion to thereby form the light absorbing layer.

In this instance, the metal oxide layer may be made of one of copper oxide (CuO or Cu₂O), aluminum oxide (Al₂O₃), silver oxide (AgO or Ag₂O), titanium oxide (TiO₂), palladium oxide (PdO), and chromium oxide (CrO, CrO₃, or Cr₂O₃), or a combination thereof.

In addition, the forming of the electrode layer may form a seed layer on the insulating layer, form the electrode layer on the seed layer, and remove the seed layer and the electrode layer formed on the insulating layer excluding the intaglio portion.

In this instance, the electrode layer may be made of a metal consisting of one of copper (Cu), aluminum (Al), gold (Au), silver (Ag), titanium (Ti), palladium (Pd), and chromium (Cr), or a combination thereof.

In addition, the method may further include forming a protective layer on the insulating layer, after the forming of the electrode layer.

In addition, the protective layer may be made of transparent resin.

In addition, the insulating layer may be made of thermosetting resin or photocurable resin.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a cross-sectional view showing a touch panel according to a preferred embodiment of the present invention;

FIGS. 2 to 8 are processing cross-sectional views showing a method of manufacturing a touch panel in the processing order according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

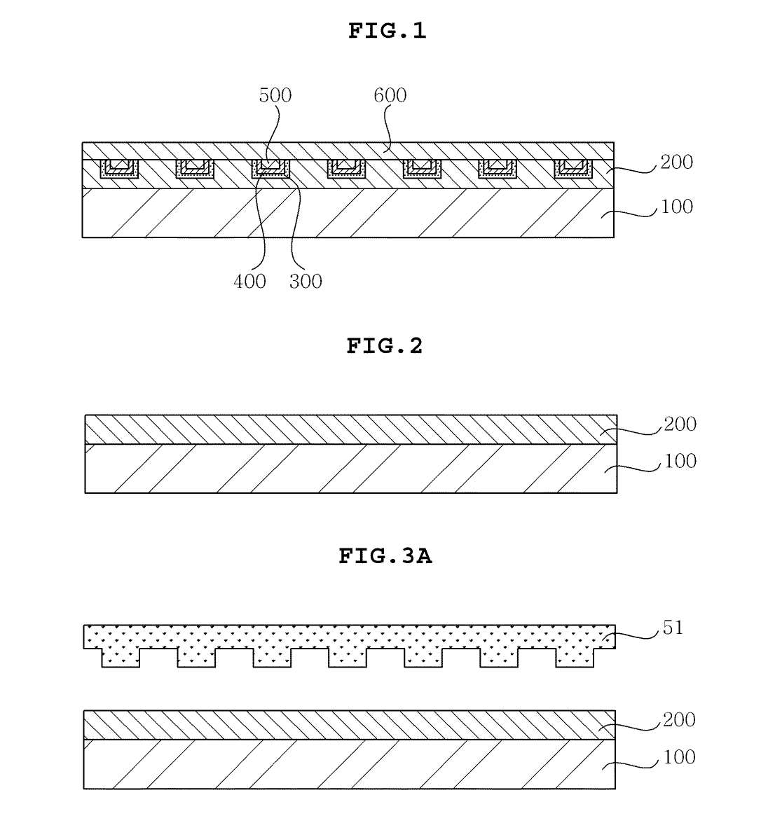

FIG. 1 is a cross-sectional view showing a touch panel according to a preferred embodiment of the present invention.

As shown in FIG. 1, a touch panel 1 according to a preferred embodiment of the present invention includes a transparent substrate 100, an insulating layer 200 that is formed on the transparent substrate 100 and has an intaglio portion 210 formed thereon, an electrode layer 500 that is embedded in the intaglio portion 210, and a light absorbing layer 300 that is formed in an inner wall of the intaglio portion 210 to be interposed between the inner wall of the intaglio portion 210 and the electrode layer 500.

The transparent substrate 100 is required to have transparency so that a user can recognize an image provided in an image display device. Based on the transparency, the transparent substrate 100 may be preferably made of polyethylene terephthalate (PET), polycarbonate (PC), polymethly methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), biaxially oriented polystyrene (K resin-containing biaxially oriented PS; BOPS), a glass, a tempered glass, etc., but is not necessarily limited thereto.

The insulating layer 200 is laminated on the transparent substrate 100. The insulating layer 200 includes the intaglio portion 210 that is recessed in the insulating layer 200 by a transcription method and the like, which will be described below. The insulating layer 200 may be made of thermosetting resin or photocurable resin (a dry film or a liquid photosensitive material).

The light absorbing layer 300 is formed in an inner wall of the intaglio portion 210 to be interposed between the inner wall of the intaglio portion 210 and the electrode layer 500 which will be described below. The light absorbing layer 300 is to prevent light reflection (glare) from occurring on the electrode layer 500 which will be described below, and made of a variety of materials which enable light absorption. As an example, the light absorbing layer 300 may be made of a material with a dark color which enables light absorption. For example, the light absorbing layer 300 may be made of ink with a dark color. More specifically, the light absorbing layer 300 may be made of black ink. Here, “ink” includes materials which have liquidity and are cured or fixed over time or in accordance with the subsequent process, for example, metals, organic materials, inorganic materials, or the like in addition to typical ink including polymer materials used in notation of characters, and the like. The ink is not limited to the black ink. Obviously, the light absorbing layer 300 may be made of a variety of ink with dark colors in which a light absorption function can be performed.

Meanwhile, the light absorbing layer 300 may be formed of a metal oxide layer. The light absorbing layer 300 may be made of a variety of metal oxides in which glare does not occur due to the dark color of the light absorbing layer 300 or characteristics of a surface of the light absorbing layer 300. For example, the light absorbing layer 300 may be made of one of the metal oxides such as copper oxide (CuO or Cu₂O), aluminum oxide (Al₂O₃), silver oxide (AgO or Ag₂O), titanium oxide (TiO₂), palladium oxide (PdO), and chromium oxide (CrO, CrO₃, or Cr₂O₃), or a combination thereof. However, examples of the metal oxides forming the light absorbing layer 300 are not necessarily limited to the above-described metal oxides. Obviously, the light absorbing layer 300 may be made of a variety of metal oxides which have dark colors or prevents glare from occurring when light is irradiated.

The electrode layer 500 is embedded in the intaglio portion 210. In this instance, the electrode layer 500 may be directly formed on the light absorbing layer 300, or as shown in FIG. 1, may be formed on a seed layer 400 in a state in which the seed layer 400 is further included in the touch panel. The electrode layer 500 may be formed through a vapor deposition process using sputtering, E-beam evaporation, or the like. However, the electrode layer 500 is not necessarily formed by the vapor deposition process, and may be formed by a plating process, inkjet printing, or the like. When the electrode layer 500 is formed by the plating process, the above-described seed layer 400 may be formed on the light absorbing layer 300 before forming the electrode layer 500. Specifically, the seed layer 400 may be formed on an exposed portion of the surface of the light absorbing layer 300 through electroless plating. The electrode layer 500 may be formed on the seed layer 400 through electroplating using the seed layer 400 as a leading wire. In this case, as shown in FIG. 1, the electrode layer 500 is embedded in the intaglio portion 210 while being formed on the seed layer 400.

As described above, the electrode layer 500 is embedded in the intaglio portion 210, and thereby may be supported by an inner wall of the intaglio portion 210. Accordingly, the touch panel 1 according to the present embodiment has improved durability compared to the conventional touch panel in which the electrode layer is protrusively formed on the transparent substrate. In addition, a portion of the electrode layer 500 which is exposed through the transparent substrate 100 may be surrounded by the light absorbing layer 300 in a state in which the seed layer 400 is interposed. Accordingly, even though light is irradiated toward the electrode layer 500 through the transparent substrate 100, the light is absorbed in the light absorbing layer 300, so that the electrode layer 500 does not generate light reflection, thereby improving visibility of the touch panel 1.

Meanwhile, the electrode layer 500 may be made of a metal consisting of one of copper (Cu), aluminum (Al), gold (Au), silver (Ag), titanium (Ti), palladium (Pd), and chromium (Cr), or a combination thereof. However, the electrode layer 500 is not limited to these kinds of metals. As long as metals have high electrical conductivity and are easily processed, the electrode layer 500 may be made of the metals. In addition, since the electrode layer 500 is made of metals, the electrode layer 500 may be formed in a mesh pattern so as not to permit light transmittance of the touch panel to be a problem due to characteristics of opaque metals.

The touch panel 1 according to the present embodiment may further include a protective layer 600. The protective layer 600 prevents separation of the electrode layer 500 from the intaglio portion 210, and is formed on the insulating layer 200 to cover the intaglio portion 210. The protective layer 600 is formed on the insulating layer 200, and therefore the intaglio portion 210 is covered by the protective layer 600. As a result, the protective layer 600 and the inner wall of the intaglio portion 210 surrounds around the electrode layer 500 so that the electrode layer 500 is supported by the protective layer 600 and the inner wall of the intaglio portion 210. The electrode layer 500 is not separated from the intaglio portion 210 by the protective layer 600. As a result, durability of the touch panel 1 may be further improved.

The protective layer 600 may be transparent resin, and as a specific example of the protective layer 600, a hard coating layer, an optical clear adhesive (OCA) layer, or an anti-reflection (AR) coating layer may be given. Here, the hard coating layer may be made of one of acrylic, epoxy, and urethane, or a combination thereof.

Meanwhile, as shown in FIG. 1, an example in which the insulating layer 200 and the protective layer 600 are laminated on a surface of the transparent substrate 100 is given. However, the present invention is not limited thereto. The insulating layer 200 and the protective layer 600 may be formed on both surfaces of the transparent substrate 100.

FIGS. 2 to 8 are processing cross-sectional views showing a method of manufacturing a touch panel in the processing order according to a preferred embodiment of the present invention.

The method of manufacturing the touch panel according to the preferred embodiment of the present invention includes step (A) of forming the insulating layer 200 on the transparent substrate 100, step (B) of forming the intaglio portion 210 on the insulating layer 200, step (C) of forming the light absorbing layer 300 in the inner wall of the intaglio portion 210, and step (D) of forming the electrode layer 500 in the intaglio portion 210.

As shown in FIG. 2, in step (A), the insulating layer 200 is formed on the transparent substrate 100.

The transparent substrate 100 is required to have transparency so that a user can recognize an image provided in an image display device. Based on the transparency, the transparent substrate 100 may be preferably made of polyethylene terephthalate (PET), polycarbonate (PC), polymethly methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), biaxially oriented polystyrene (K resin-containing biaxially oriented PS; BOPS), a glass, a tempered glass, etc., but is not necessarily limited thereto.

The insulating layer 200 may be made of thermosetting resin or photocurable resin (a dry film or a liquid photosensitive material) so that the insulating layer 200 is subjected to a patterning process which will be described below and then cured by heat or light (UV). A specific patterning process and curing process of the insulating layer 200 will be described below.

In step (B), the intaglio portion 210 is formed on the insulating layer 200.

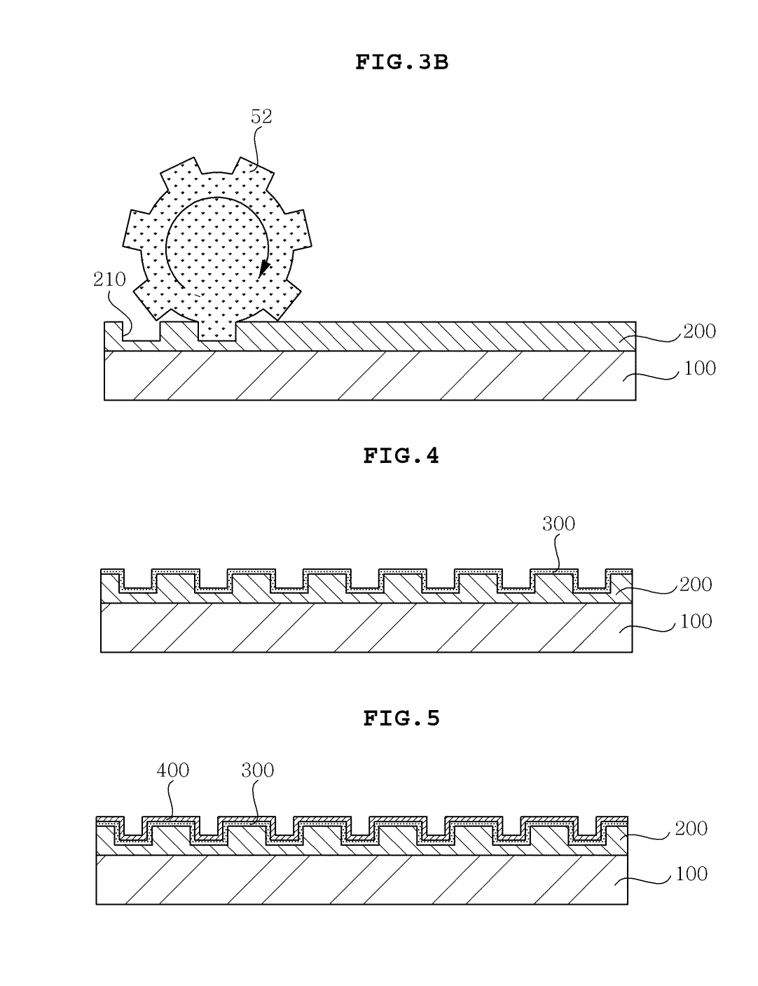

In step (B), as shown in FIGS. 3A and 3B, a stamp may be used to form the intaglio portion 210 on the insulating layer 200. The intaglio portion 210 may be formed such that the stamp is transcribed into the insulating layer 200 in a thickness direction of the insulating layer 200. In this instance, the intaglio portion 210 may be formed such that the stamp penetrates the insulating layer 200, but may be formed such that residues remain without penetrating the insulating layer 200 when using the stamp as shown in figures. The electrode layer 500 may be formed in the intaglio portion 210 while subjected to the following process. Accordingly, the insulating layer 200 is preferably patterned based on a pattern of the electrode layer 500. The stamp is not particularly limited as long as the stamp is processed to be engraved in relief. The stamp may be a planar stamp 51 as shown in FIG. 3A, or a circuit stamp 52 as shown in FIG. 3B. When the circuit stamp 52 is used, a process of manufacturing the touch panel may be consecutively performed by a roll to roll process.

The insulating layer 200 is patterned by the stamps 51 and 52, and then cured. A method of curing the insulating layer 200 differs depending on a material of the insulating layer 200. When the insulating layer 200 is made of thermosetting resin, the insulating layer 200 is cured by heat, and when made of photocurable resin, the insulating layer 200 is cured by light (UV).

In step (C), the light absorbing layer 300 is formed in the intaglio portion 210.

The light absorbing layer 300 is to prevent light reflection (glare) of the electrode layer 500 from occurring, and may be made of a variety of materials which enable light absorption. As an example, the light absorbing layer 300 may be made of an ink material with a dark color which enables light absorption. For example, the light absorbing layer 300 may be made of ink, and as a more specific example, the light absorbing layer 300 may be made of black ink. A specific example of a process in which the light absorbing layer 300 is made of ink is as follows.

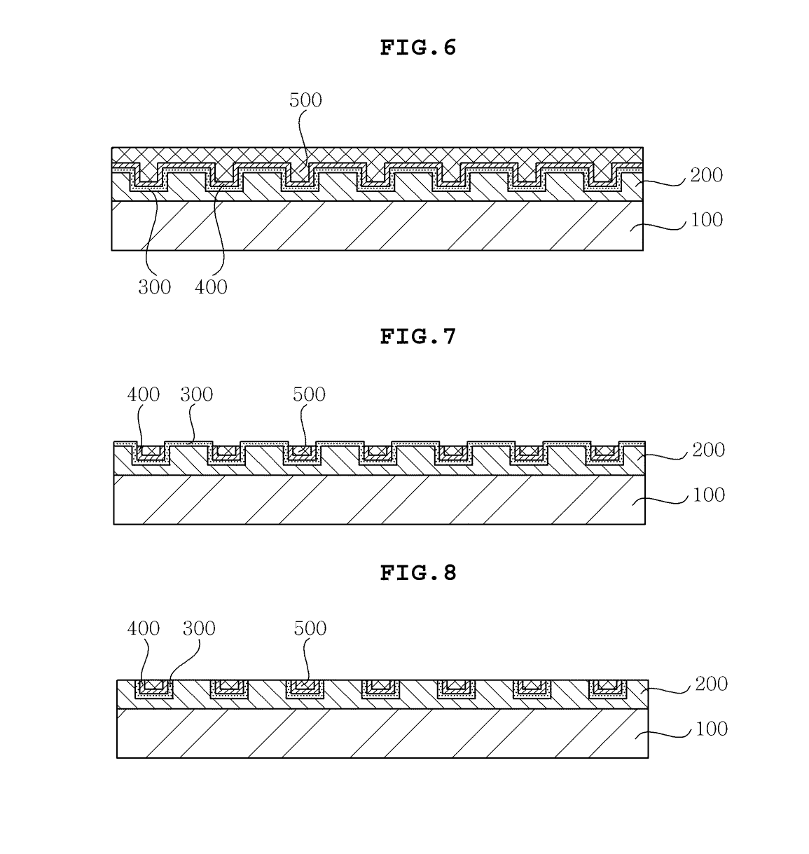

When the transparent substrate 100 having been subjected to step (B), that is, the transparent substrate 100 having the insulating layer 200 in which the intaglio portion 210 is patterned is immersed in the ink and then dried, the ink is formed, as a coating film, on a surface of the insulating layer 200 including the inner wall of the intaglio portion 210 as shown in FIG. 4. In this instance, when the ink formed on the remaining portion of the insulating layer 200 except the intaglio portion 210 is removed by release agent such as an alkaline aqueous solution or by a variety of ink removal methods known in the related art, the ink exists only on the inner wall of the intaglio portion 210 in the form of a coating film. The above-described ink removal process may be subsequently performed after the transparent substrate 100 is immersed in the ink to be dried, or as shown in FIG. 7, may be performed after an etching process (see, FIG. 6) of the electrode layer 500 which will be described below is performed.

Meanwhile, the light absorbing layer 300 may be formed of a metal oxide layer. The light absorbing layer 300 may be made of a variety of metal oxides with dark colors, or metal oxides which do not cause glare due to characteristics of a surface of the metal oxide. For example, the light absorbing layer 300 may be made of one of copper oxide (CuO or Cu₂O), aluminum oxide (Al₂O₃), silver oxide (AgO or Ag₂O), titanium oxide (TiO₂), palladium oxide (PdO), and chromium oxide (CrO, CrO₃, or Cr₂O₃), or a combination thereof. However, the metal oxides forming the light absorbing layer 300 are not limited to the above-described examples. Obviously, the light absorbing layer 300 may be made of various other metal oxides which have dark colors or prevent glare from occurring when light is irradiated.

A process in which the light absorbing layer 300 is formed of the metal oxide layer is performed in the similar manner as the process in which the light absorbing layer 300 is made of the ink. Specifically, first, the metal oxide layer is formed on the insulating layer 200 by a vapor deposition method or the like. Next, the metal oxide layer formed on the remaining portion of the insulating layer 200 except the intaglio portion 210 is removed by etching, or the like, so that the light absorbing layer 300 including the metal oxide layer may be formed in the inner wall of the intaglio portion 210.

In step (D), the electrode layer 500 is formed in the inner wall of the intaglio portion 210.

The electrode layer 500 may be formed through a vapor deposition process using sputtering, e-beam evaporation, or the like. However, the electrode layer 500 is not necessarily formed by the vapor deposition process, and may be formed by a plating process, inkjet printing, or the like. When the electrode layer 500 is formed by the plating process, the seed layer 400 may be formed on the light absorbing layer 300. Specifically, the seed layer 400 may be formed on the insulating layer 200 including an exposed surface of the light absorbing layer 300 through electroless plating as shown in FIG. 5. As shown in FIG. 6, the electrode layer 500 may be formed on the seed layer 400 through electroplating using the seed layer 400 as a leading wire. Next, the seed layer 400 and the electrode layer 500 which are formed on the remaining portion of the insulating layer 200 except the intaglio portion 210 on the seed layer 400 and the electrode layer 500 may be removed by an etching process as shown in FIG. 7. The electrode layer 500 having been subjected to the etching process is not protrusively formed on the transparent substrate 100, and remains in a state of being embedded in the intaglio portion 210.

Meanwhile, the electrode layer 500 may be made of a metal consisting of one of copper (Cu), aluminum (Al), gold (Au), silver (Ag), titanium (Ti), palladium (Pd), and chromium (Cr), or a combination thereof, and may be formed the above-described process. However, the electrode layer 500 is not limited to these kinds of metals. As long as metals have high electrical conductivity and are easily processed, the electrode layer 500 may be made of the metals. In addition, since the electrode layer 500 is made of metals, the electrode layer 500 may be formed in a mesh pattern so as not to permit light transmittance of the touch panel 1, which is a problem due to the characteristics of opaque metals.

Meanwhile, in a case in which a process of removing the black ink formed on the remaining portion of the insulating layer 200 except the intaglio portion 210 is performed after the above-described process of forming the electrode layer 500, the black ink formed on the remaining portion of the insulating layer 200 except the intaglio portion 210 is exposed to the outside as shown in FIG. 7 when the seed layer 400 and the electrode layer 500 which are formed on the remaining portion of the insulating layer 200 except the intaglio portion 210 are removed by etching. In this manner, the exposed black ink may be completely removed by the above-described method of removing the ink as shown in FIG. 8.

Meanwhile, the method of manufacturing the touch panel may further include step (E) of forming a protective layer 600 on the insulating layer 200 after step (D).

Step (E) is performed in order to prevent separation of the electrode layer 500 toward an open side (upward in FIG. 8) of the insulating layer 200. The protective layer 600 is formed on the insulating layer 200 as shown in FIG. 1, so that the intaglio portion 210 is covered by the protective layer 600. As a result, the protective layer 600 and the inner wall of the intaglio portion 210 surround around the electrode layer 500. The separation of the electrode layer 500 from the intaglio portion 210 may be prevented by the protective layer 600, thereby further improving durability of the touch panel.

The protective layer 600 may be made of transparent resin, and as specific examples of the protective layer 600, a hard coating layer, an optical clear adhesive (OCA) layer, or an anti-reflection (AR) coating layer may be given. Here, the hard coating layer may be made of one of acrylic, epoxy, and urethane, or a combination thereof.

As described above, according to the embodiments, the electrode layer is embedded in the intaglio portion of the insulating layer to be supported by the inner wall of the intaglio portion, and when the protective layer is further formed, the separation of the electrode layer from the insulating layer may be prevented, thereby improving durability of the touch panel.

In addition, an exposure portion of the electrode layer which is exposed through the transparent substrate may be surrounded by the light absorbing layer, and therefore glare on the electrode layer may be prevented even though light is irradiated toward the electrode layer, thereby improving visibility of the touch panel.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations, or equivalent arrangements should be considered to be within the scope of the invention, and the detailed scope of the invention will be disclosed by the accompanying claims.

What is claimed is:

1. A touch panel, comprising:
a transparent substrate;
an insulating layer that is formed on the transparent substrate and has an intaglio portion formed thereon;
an electrode layer that is embedded in the intaglio portion; and
a light absorbing layer that is formed in an inner wall of the intaglio portion to be interposed between the inner wall of the intaglio portion and the electrode layer.

2. The touch panel as set forth in claim 1, further comprising:
a seed layer that is formed between the light absorbing layer and the electrode layer.

3. The touch panel as set forth in claim 1, further comprising:
a protective layer that is formed on the insulating layer.

4. The touch panel as set forth in claim 3, wherein the protective layer is made of transparent resin.

5. The touch panel as set forth in claim 1, wherein the insulating layer is made of thermosetting resin or photocurable resin.

6. The touch panel as set forth in claim 1, wherein the electrode layer is made of a metal consisting of one of copper (Cu), aluminum (Al), gold (Au), silver (Ag), titanium (Ti), palladium (Pd), and chromium (Cr), or a combination thereof.

7. The touch panel as set forth in claim 1, wherein the light absorbing layer includes an ink layer.

8. The touch panel as set forth in claim 7, wherein the ink layer is made of black ink.

9. The touch panel as set forth in claim 1, wherein the light absorbing layer is formed of a metal oxide layer.

10. The touch panel as set forth in claim 9, wherein the metal oxide layer is made of one of copper oxide (CuO or Cu₂O), aluminum oxide (Al₂O₃), silver oxide (AgO or Ag₂O), titanium oxide (TiO₂), palladium oxide (PdO), and chromium oxide (CrO, CrO₃, or Cr₂O₃), or a combination thereof.

11. A method of manufacturing a touch panel, comprising: forming an insulating layer on a transparent substrate;
forming an intaglio portion on the insulating layer;
forming a light absorbing layer on an inner wall of the intaglio portion; and
forming an electrode layer in the intaglio portion.

12. The method as set forth in claim 11, wherein the forming of the intaglio portion patterns the insulating layer using a stamp to form the intaglio portion.

13. The method as set forth in claim 11, wherein the forming of the light absorbing layer immerses the transparent substrate on which the insulating layer is formed in ink, dries the immersed transparent substrate, and removes the ink formed on the insulating layer excluding the intaglio portion to thereby form the light absorbing layer.

14. The method as set forth in claim 13, wherein the ink is black ink.

15. The method as set forth in claim 11, wherein the forming of the light absorbing layer forms a metal oxide layer on the insulating layer, and removes the metal oxide layer formed on the insulating layer excluding the intaglio portion to thereby form the light absorbing layer.

16. The method as set forth in claim 15, wherein the metal oxide layer is made of one of copper oxide (CuO or Cu₂O), aluminum oxide (Al₂O₃), silver oxide (AgO or Ag₂O), titanium oxide (TiO₂), palladium oxide (PdO), and chromium oxide (CrO, CrO₃, or Cr₂O₃), or a combination thereof.

17. The method as set forth in claim 11, wherein the forming of the electrode layer forms a seed layer on the insulating layer, forms the electrode layer on the seed layer, and removes the seed layer and the electrode layer formed on the insulating layer excluding the intaglio portion.

18. The method as set forth in claim 17, wherein the electrode layer is made of a metal consisting of one of copper (Cu), aluminum (Al), gold (Au), silver (Ag), titanium (Ti), palladium (Pd), and chromium (Cr), or a combination thereof.

19. The method as set forth in claim 11, further comprising:
forming a protective layer on the insulating layer, after the forming of the electrode layer.

20. The method as set forth in claim 19, wherein the protective layer is made of transparent resin.
